(19) United States
(12) Patent Application Publication
(10) Pub. No.: US 2024/0396285 A1
(43) Pub. Date: Nov. 28, 2024

(54) Apparatus, Method and System for Scalable Optical Cavity Locking

(71) Applicant: NU QUANTUM LTD, Cambridgeshire (GB)

(72) Inventors: Bethany Foxon, Cambridgeshire (GB); Tim Bossanyi, Cambridgeshire (GB)

(73) Assignee: NU QUANTUM LTD, Cambridgeshire (GB)

(21) Appl. No.: 18/769,773

(22) Filed: Jul. 11, 2024

Related U.S. Application Data
(63) Continuation-in-part of application No. PCT/GB2024/051354, filed on May 24, 2024.

(30) Foreign Application Priority Data
May 26, 2023 (GB) 2307891.8

(51) Int. Cl. H01S 3/13; H01S 3/00; H01S 3/1109

(52) U.S. Cl. CPC H01S 3/1305; H01S 3/0014; H01S 3/1109

(57) ABSTRACT

According to aspects of the disclosure, an apparatus, system and method for stabilising the length of a plurality of optical cavities is provided. The apparatus comprises an optical light source configured to output an incident light beam. The apparatus also includes a separating means configured to receive the incident light beam output from the optical source and split the received incident light beam so as to output two or more light beams. The apparatus further includes a plurality of optical cavities, where each optical cavity of the plurality of optical cavities is configured to receive one of the light beams output from the separating means and transmit or reflect a portion of light indicative of whether the optical cavity is on resonance with the optical light source. Each optical cavity is also configured to contain a matter qubit within the optical cavity. Each matter qubit is configured to capture photons to distribute quantum entanglement, where a rate of entanglement is enhanced by the Purcell effect. Each optical cavity is further configured to be connected to an actuator. The actuator is configured to tune the length of the optical cavity based on the portion of light transmitted or reflected from the optical cavity to be on resonance with the optical source in order to lock the optical cavity to the optical source. The matter qubit is the same for each optical cavity. The incident light beam is detuned by a ratio of two integers, a and b where a b denotes a fixed fraction, from a transition wavelength of the matter qubit to ensure that, for each optical cavity, there is at least one point within a travel range of the actuator where a dual-resonance condition is met such that the optical cavity is simultaneously resonant with the matter qubit and the incident light beam.

The present disclosure relates to an apparatus, system and method for locking or stabilising a length of a plurality of optical cavities at the same time. The disclosure finds utility in, for example, various quantum networking and quantum computing schemes.

### BACKGROUND

Optical cavities containing matter qubits are thought to be key components in the development of quantum computing and quantum networking devices because they enable the state of the qubit within the optical cavity to be controlled. The matter qubit captures photons to distribute quantum entanglement throughout the quantum system.

An optical cavity is a device that forms a resonator by confining light along a closed path using reflective optical elements. It is a resonator that only supports specific frequencies/wavelengths of light. The wavelengths of light which are supported by the optical cavity depends on the length of the optical cavity. In particular, light can only enter the optical cavity if the length of the optical cavity is an integer multiple of the wavelength of the light. Light which is not of the correct wavelength is reflected from the cavity. In order for an optical cavity to be used for practical applications, it is therefore necessary to reliably tune and lock the length of the optical cavity.

To make a functioning quantum computing or networking system will require the use of multiple optical cavities, all of which will need to be locked. At present, locking or stabilising the length of an optical cavity typically requires components which can be bulky and/or expensive. When locking a plurality of optical cavities, these expensive and bulky components are required to be duplicated. The cost and space required for these components thereby limits the practical applications that are currently feasibly obtainable using optical cavities.

The present disclosure has been devised in the foregoing context.

### BRIEF SUMMARY

In one aspect, an apparatus for stabilising the length of a plurality of optical cavities is provided. The apparatus includes an optical light source configured to output an incident light beam. The apparatus also includes a separating means configured to receive the incident light beam output from the optical source and split the received incident light beam so as to output two or more light beams. The apparatus further includes a plurality of optical cavities, where each optical cavity of the plurality of optical cavities is configured to receive one of the light beams output from the separating means and transmit or reflect a portion of light indicative of whether the optical cavity is on resonance with the optical light source. Each optical cavity is also configured to contain a matter qubit within the optical cavity. Each matter qubit is configured to capture photons to distribute quantum entanglement, where a rate of entanglement is enhanced by the Purcell effect. Each optical cavity is further configured to be connected to an actuator. The actuator is configured to tune the length of the optical cavity based on the portion of light transmitted or reflected from the optical cavity to be on resonance with the optical source in order to lock the optical cavity to the optical source. The matter qubit is the same for each optical cavity. The incident light beam is detuned by a ratio of two integers, a and b where a b denotes a fixed fraction, from a transition wavelength of the matter qubit to ensure that, for each optical cavity, there is at least one point within a travel range of the actuator where a dual-resonance condition is met such that the optical cavity is simultaneously resonant with the matter qubit and the incident light beam.

Advantageously, providing a separating means between the plurality of optical cavities and the optical light source allows the length of each optical cavity to be stabilised simultaneously. Further advantageously, it is not necessary to provide a separate optical light source or other equipment for each optical cavity. This reduction in component duplication reduces both equipment costs and an amount of space required to contain all of the equipment.

Further advantageously, detuning the incident light beam from the matter qubit wavelength prevents unwanted excitation of the matter qubit and ensures that the incident light beam can be filtered out from a path of the entangled photons.

An optical cavity is said to be on resonance or resonant when the length of the optical cavity is a half integer number of wavelengths. To lock the cavity length using an incident light beam of one wavelength, whilst enhancing the matter qubit at a different wavelength, we therefore require this condition to be met for both wavelengths, i.e. we have a dual-resonance condition. That is, the dual-resonance condition is met when the optical cavity is resonant with both the wavelength of the photon emitted from the matter qubit and the locking wavelength.

When an arbitrary wavelength of the incident light beam is used, it is not possible to guarantee there will be a single cavity length at which the dual-resonance condition is met. By introducing a small amount of tunability to the initially arbitrary wavelength, the system can be tuned to ensure that there is a single point at which the dual-resonance condition is met. Furthermore, stabilising the length of a plurality of optical cavities using a single optical light source outputting an incident light beam with an initially arbitrary wavelength tunable by up to one Free Spectral Range, would require all of the optical cavities to initially have the same length, at least to within a tuning tolerance of the actuator. This is difficult to engineer using standard manufacturing processes.

However, constraining the choice of incident light beam wavelength to be a fixed fraction of the wavelength of the matter qubit resolves this problem. It is then not necessary for all of the optical cavities to initially have the same length. For example, if the incident light beam is chosen to have a wavelength half that of the photon emitted from the matter qubit, then it can be guaranteed that all of the emitter resonances will have a corresponding locking resonance. The wavelength of the incident light beam is not limited to being half that of the emitted photon, and any fixed fraction or multiple of the incident light beam wavelength which is guaranteed to repeat within a travel range of the actuator may be used.

Advantageously, this arrangement provides a cost-effective and compact way of stabilising multiple optical cavities, especially for applications which require a very large number of stable optical cavities (such as in data-centres). This is especially useful in cases where the required wavelengths of light are far away from convenient stable reference wavelengths, such as those wavelengths obtained from transitions in neutral atoms, because stable optical light sources can be prohibitively expensive. Therefore, providing a separate sufficiently stable optical light source for each and every optical cavity may not be economically feasible. In addition, each optical light source requires an offset lock, and offset locks typically require high-frequency electronics which are expensive and difficult to engineer. Increasing the number of optical cavities which can be locked using a single optical light source thereby leads to a chain-reaction of cost and space savings.

Optionally, the apparatus may further include, for each optical cavity of the plurality of optical cavities, a first modulator arranged between the separating means and the optical cavity.

Advantageously, providing a modulator between the separating means and the optical cavity enables the wavelength of the locking light emitted by the optical light source to be individually fine-tuned for each cavity. Manufacturing tolerances mean that each optical cavity is likely to be slightly different. In addition, the matter qubit wavelength and the incident light beam wavelength may interact with the mirrors of the optical cavity in slightly different ways. These differences can have an impact on the length of the cavity experienced by each of the matter qubit wavelength and the incident light beam wavelength.

The modulator applies a phase shift to the frequency of the incident light beam to account for the optical effects and manufacturing tolerances. Each optical cavity has a corresponding modulator. This ensures that each optical cavity remains simultaneously resonant with both the matter qubit and the incident light beam. The plurality of optical cavities can therefore still be simultaneously locked despite the optical cavities not being identical.

The first modulator may comprise an acousto-optic modulator (AOM) or an electro-optic modulator (EOM).

The apparatus may also include a second modulator, arranged between the optical light source and the separating means to apply a phase shift to the incident light beam. The second modulator is an EOM.

The apparatus may also include a second separating means arranged between the optical light source and the second modulator to split the incident light beam into a plurality of light beams.

Advantageously, this enables an even greater number of optical cavities to be tuned or stabilised simultaneously. The number of optical cavities which can be locked is limited by the amount of light which can be output by a single EOM and a minimum amount of light required by each optical cavity. As the amount of light received by an optical cavity decreases, noise experienced at the connected electronics forms a larger fraction of any detected signals. When there is too little light, the signal to noise ratio of a locking signal is degraded. This degradation leads to a reduction in the robustness of the cavity lock. Once the maximum transmission power of light through an EOM has been reached, more EOMs are required. Using a second separating means between the optical light source and the EOM to split the incident light beam allows the light from the optical light source to be sent to multiple EOMs, which in turn can be used to stabilise the length of multiple optical cavities. Thus, the use of a second separating means advantageously allows a single stable optical light source to be used to reliably stabilise and lock the lengths of a larger number of optical cavities. This helps minimise the cost and space requirements of the equipment needed to lock an even greater number of optical cavities.

The apparatus may also include, for each optical cavity, a measuring means for measuring a fraction of light transmitted or reflected from the optical cavity.

The apparatus may also comprise, for each actuator, a means for scanning the actuator.

The wavelength of the incident light beam may be chosen to be λ₁=λ_{q}*α/b, where α<N, λ_{q} is the transition wavelength of the matter qubit and is fixed, λ₁ is the wavelength of the incident light beam, N=z/λ_{q} where N is a number greater than 1 and not necessarily an integer number, z is a travel range of the actuator, a and b are the integers of claim 1, where a/b is a simplified fraction.

The ratio in which incident light beam is detuned from the wavelength of the matter qubit may include two integers less than 10. The ratio may include two integers less than 5. The ratio of the wavelength of the incident light beam to the wavelength of the matter qubit may be 1:2, 2:3, 3:4, 4:5, 2:1, 3:2, 4:3 or 5:4. Advantageously, these ratios enable the wavelength of the incident light beam to be kept within a range which is easiest to work with in practical situations. Furthermore, it is typically easier to source parts which work with or emit light within this wavelength range.

The wavelength of the incident light beam may be within the range 600-1600 nm. Advantageously, this wavelength range is easiest to work with in practical situations, as mentioned above.

The separating means may be an optical splitter, the matter qubit may comprise a neutral atom or a trapped ion, the actuator may be a piezo actuator and the optical light source may be a laser. Advantageously, these are all standard components in the field so it is not necessary to try to source or use extra-specialised or rare equipment. This minimises costs and complexity of use.

Each of the optical cavities may include a dual-band coating. Advantageously, this enables each optical cavity to be reflective at both the locking (incident light beam) wavelength and the matter qubit transition wavelength.

The apparatus may also include, for each of the optical cavities, a locking means to maintain a length of the optical cavity. Advantageously, this ensures that the length of the optical cavity remains stable, correcting for any thermal or vibrational shifts.

The actuator may be configured to lock each of the optical cavities to be on resonance with the optical light source using a Pound-Drever-Hall technique, a side-of-peak locking technique, or a dither locking technique.

The apparatus may be for use in quantum computing and/or quantum networking applications. Stabilising the length of a plurality of optical cavities is a requirement for various quantum computing and networking schemes. Therefore, providing an apparatus which performs this function for use in this field advantageously enables research and practical applications in these fields to progress.

The apparatus may also include a stabilising means for stabilising the optical light source. The stabilising means may generate fixed fraction locking light at a fixed fraction wavelength using a stable reference at a qubit transition wavelength.

Advantageously, the stabilising means ensures that the wavelength of the light emitted from the optical light source remains stable. By ensuring that the optical light source is stable, the length of an optical cavity can be more reliably stabilised.

The stabilising means may comprise a second harmonic generator or an optical transfer cavity for generating the fixed fraction locking light.

Advantageously, the second harmonic generator or optical transfer cavity can be used to directly generate the fixed fraction locking light without the need for any form of optical light source offset lock. For example, if the matter qubit in the optical cavity comprises an alkali element, then an atomic vapour cell can provide the exact qubit transition wavelength as a reference. This wavelength can then be halved to provide the wavelength of the fixed fraction locking light, and the second harmonic generator or optical transfer cavity can generate the fixed fraction locking light with this halved wavelength.

The optical light source may be stabilised by reference to an atomic vapour cell, a stabilized HeNe laser, or an optical frequency comb. The atomic vapour cell may comprises a Rb cell.

In another aspect of the invention, a system for stabilising the length of a plurality of optical cavities is provided. The system comprises at least two apparatuses according to any of claims 1 to 14, and a reference optical source configured to output a reference incident light beam. The system further includes a reference separating means configured to receive the reference incident light beam output from the reference optical source and split the received reference incident light beam so as to output two or more reference light beams, such that each optical light source of the at least two apparatuses is stabilised by reference to one of the output reference light beams.

Advantageously, this increases the number of optical cavities which can be locked at the same time. Once a maximum power of a single optical light source has been reached, multiple optical light sources can be offset-locked relative to a stable single reference optical source.

In yet another aspect of the invention, a method for stabilising the length of a plurality of optical cavities is provided. The method includes outputting, by an optical light source, an incident light beam. The method also includes receiving, at a separating means, the incident light beam output from the optical source. The method also includes splitting, by the separating means, the received incident light beam so as to output two or more light beams. The method also includes, for each optical cavity of a plurality of optical cavities, receiving one of the light beams output from the separating means; transmitting or reflecting a portion of light indicative of whether the optical cavity is on resonance with the optical light source; capturing, by a matter qubit located in the optical cavity, photons to distribute quantum entanglement, wherein a rate of entanglement is enhanced by the Purcell effect; and tuning, by an actuator connected to the optical cavity, the length of the optical cavity based on the portion of light transmitted or reflected from the optical cavity to be on resonance with the optical source in order to lock the optical cavity to the optical source. The matter qubit is the same for each optical cavity, and the incident light beam is detuned by a ratio of two integers, a and b where a b denotes a fixed fraction, from a transition wavelength of the matter qubit to ensure that, for each optical cavity, there is at least one point within a travel range of the actuator where a dual-resonance condition is met such that the optical cavity is simultaneously resonant with the matter qubit and the incident light beam.

The method may also include measuring, by a measuring means, the portion of light to determine a fraction of light transmitted or reflected from the optical cavity.

The method may also include locking, by a locking means, a length of the optical cavity when the determined fraction of light transmitted or reflected is within a predetermined range. Advantageously, this retains the length of the optical cavity The length of the optical cavity may be locked by measuring that the determined fraction of light transmitted is at a maximum or that the determined fraction of light reflected is at a minimum. The optical cavity may be locked using a Pound-Hall-Drever technique, a side-of-peak locking technique, or a dither locking technique.

Many modifications and other embodiments of the inventions set out herein will come to mind to a person skilled in the art to which these inventions pertain in light of the teachings presented herein. Therefore, it will be understood that the disclosure herein is not to be limited to the specific embodiments disclosed herein. Moreover, although the description provided herein provides example embodiments in the context of certain combinations of elements, steps and/or functions may be provided by alternative embodiments without departing from the scope of the invention.

### BRIEF DESCRIPTION OF THE SEVERAL VIEWS OF THE DRAWINGS

Embodiments of the invention will now be described, by way of example only, with reference to the accompanying drawings in which like reference numerals are used to depict like parts. In the drawings:

FIG. 1 shows an embodiment of an apparatus for locking a plurality of optical cavities in accordance with aspects of the present disclosure.

FIG. 2 shows another embodiment of an apparatus for locking a plurality of optical cavities in accordance with aspects of the present disclosure.

FIG. 3 shows a graph showing transmission of light through an optical cavity according to an embodiment of the invention.

FIG. 4 shows a method for stabilising the length of a plurality of optical cavities in accordance with aspects of the present disclosure.

FIG. 5 shows an embodiment of a system for locking a plurality of optical cavities in accordance with aspects of the present disclosure.

FIG. 6 shows another embodiment of an apparatus for locking a plurality of optical cavities in accordance with aspects of the present disclosure.

FIG. 7 shows a further embodiment of an apparatus for locking a plurality of optical cavities in accordance with aspects of the present disclosure.

### DETAILED DESCRIPTION

Hereinafter, embodiments of the disclosure are described with reference to the accompanying drawings. However, it should be appreciated that the disclosure is not limited to the embodiments, and all changes and/or equivalents or replacements thereto also belong to the scope of the disclosure. The same or similar reference denotations may be used to refer to the same or similar elements throughout the specification and the drawings.

As used herein, the terms “have,” “may have,” “include,” or “may include” a feature (e.g., a number, function, operation, or a component such as a part) indicate the existence of the feature and do not exclude the existence of other features.

As used herein, the terms “A or B,” “at least one of A and/or B,” or “one or more of A and/or B” may include all possible combinations of A and B. For example, “A or B,” “at least one of A and B,” “at least one of A or B” may indicate all of (1) including at least one A, (2) including at least one B, or (3) including at least one A and at least one B.

As used herein, the terms “first” and “second” may modify various components regardless of importance and do not limit the components. These terms are only used to distinguish one component from another. For example, a first user device and a second user device may indicate different user devices from each other regardless of the order or importance of the devices. For example, a first component may be denoted a second component, and vice versa without departing from the scope of the disclosure.

It will be understood that when an element (e.g., a first element) is referred to as being (mechanically, operatively or communicatively) “coupled with/to,” or “connected with/to” another element (e.g., a second element), it can be coupled or connected with/to the other element directly or via a third element. In contrast, it will be understood that when an element (e.g., a first element) is referred to as being “directly coupled with/to” or “directly connected with/to” another element (e.g., a second element), no other element (e.g., a third element) intervenes between the element and the other element.

As used herein, the terms “configured (or set) to” may be interchangeably used with the terms “suitable for,” “having the capacity to,” “designed to,” “adapted to,” “made to,” or “capable of” depending on circumstances.

It is to be understood that the singular forms “a,” “′an,” and “the” include plural references unless the context clearly dictates otherwise.

The terms as used herein are provided merely to describe some embodiments thereof, but not to limit the scope of other embodiments of the disclosure. All terms including technical and scientific terms used herein have the same meaning as commonly understood by one of ordinary skill in the art to which the embodiments of the disclosure belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

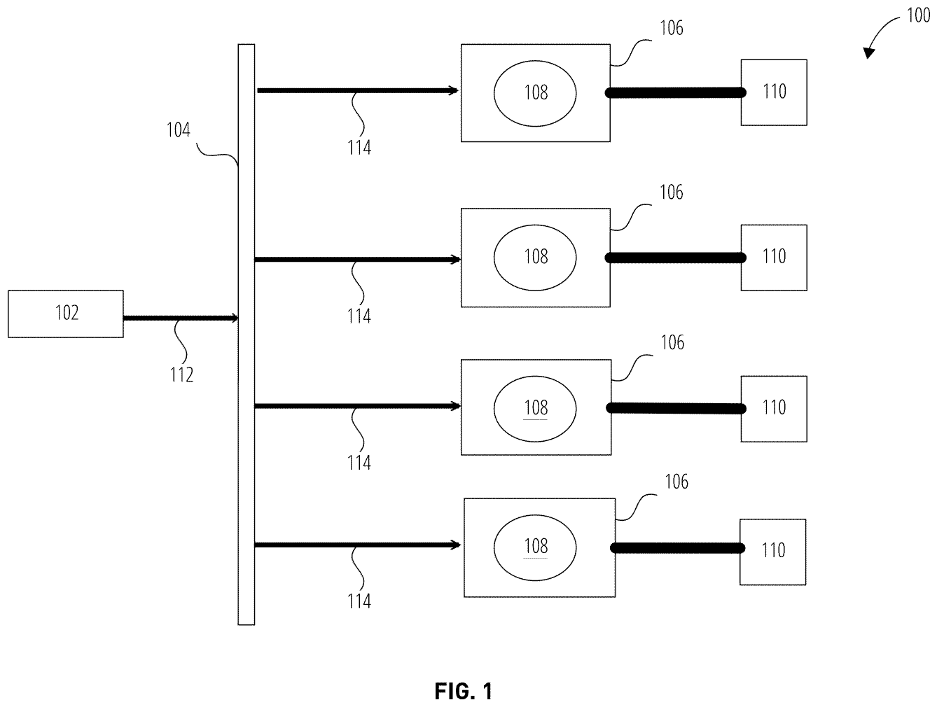

With reference now to the figures, FIG. 1 shows a schematic illustration of an apparatus 100 for locking a plurality of optical cavities in accordance with aspects of the present disclosure. The apparatus 100 comprises an optical light source 102, a separating means 104, a plurality of optical cavities 106 each containing a matter qubit 108, and a plurality of actuators 110.

The optical light source 102, which may be a laser, is configured to generate and output an incident light beam 112. The incident light beam 112 is received at the separating means 104, such as an optical splitter, which splits or divides the incident light beam 112 into a plurality of light beams 114. In this example, the incident light beam 112 is divided into four light beams 114, but this is exemplary and the separating means 104 may split or divide the incident light beam 112 into any number of light beams 114. The light beams 114 have the same wavelength as the incident light beam 112. The light beams 114 may differ only from the incident light beam 112 in terms of their intensities, such that the intensity of the light beams 114 may be less than the intensity of the incident light beam 112 by virtue of the incident light beam 112 being split into the plurality of light beams 114. Each light beam 114 may be transmitted into an optical cavity 106 to enable cavity stabilisation.

An optical cavity 106 (which may also be referred to as an interface cavity or science cavity) is formed between a first reflective surface and a second reflective surface. The first reflective surface and the second reflective surface may be formed of the same, or different, substrates. Each substrate may be provided with a coating to improve the reflectivity of the surface. The coating may be a dual-band coating to enable the optical cavity 106 to be reflective at both the incident light beam 112 wavelength and the matter qubit transition wavelength. Each optical cavity 106 may be arranged as a Fabry Perot-type cavity with a concave-concave structure, with at least one reflective surface being formed to have a concave mirrored surface with a very high reflection coefficient in the wavelength of interest in the region of 99.9%.

Providing a concave-concave cavity allows the trapped ion or neutral atom providing the matter qubit 108 to be located in the middle of the optical cavity 106 at the cavity waist where the Purcell enhancement effect is greatest. In this respect, the optical cavity 106 provides a light-matter interface for interacting with the matter qubit 108, and enhancing the transmission or absorption of single photons by the matter qubit 108. This facilitates photonic manipulation and control of the matter qubit 108, for example, to aid the performance of qubit gate operations in a quantum computer.

A matter qubit 108 is provided within the optical cavity 106. Each optical cavity 106 contains a matter qubit 108 made of the same material. The matter qubit 108 may be a quantum object such as a trapped ion or a neutral atom which may, for example, serve as a qubit in a quantum computer or quantum network. The matter qubit 108 may act as a single photon generating material, or a single photon emitter, which generates single photons in response to electrical or optical excitation of the matter qubit 108.

The matter qubit is placed in in the optical cavity to provide Purcell enhancement. Purcell enhancement is an effect which enhances the spontaneous emission rate of the matter qubit 108 in response to the matter qubit 108 interacting with the optical cavity 106. This effect also leads to an increase in the efficiency of quantum entanglement distribution of entangled particles.

Each optical cavity 106 is connected to an actuator 110, such as a piezoelectric transducer. The actuator 110 may be used to actuate a mechanical structure supporting at least part of an optical cavity 106 to finetune the length of the optical cavity 106. One way of detecting the amount of tuning required is to transmit light from an optical light source into the optical cavity 106, where the portion of light from the optical light source 102 that is transmitted or reflected from the optical cavity 106 indicates the amount of tuning required by the actuator 110. The actuator 110 is controlled to maintain a steady length and resonant frequency of the connected optical cavity 106.

The length of the optical cavity 106 can be tuned by the actuator 110 such that the optical cavity 106 is on resonance with a transition wavelength of the matter qubit 108. The transition wavelength is the wavelength of a single photon captured by the matter qubit 108. Thus, by actuating the mechanical structure supporting the optical cavity 106, the actuator 110 can tune the length of the optical cavity 106 to lock the optical cavity 106 to both the optical light source 102 and the transition wavelength of the matter qubit 108.

The optical cavity is on resonance with both the matter qubit 108 and the incident light beam when the light transmitted from the optical cavity 106 is at a maximum value or, equally, when the light reflected by the optical cavity is at a minimum value. The length of the optical cavity 106 may be locked when this criterium is met.

When the incident light beam 112 is divided into a plurality of light beams 114, with each optical cavity 106 receiving one of the light beams 114, then each optical cavity 106 of the plurality of optical cavities can be locked to the same optical light source 102. That is, one optical light source 102 can be used to lock the lengths of a plurality of optical cavities 106 by splitting the incident light beam 112 output by the optical light source 102 before the incident light beam 112 reaches the optical cavities 106. Furthermore, this enables additional components placed before the separating means 104 divides the incident light beam (such as stable frequency references or electro-optic modulators) to also be used for all or some of the plurality of optical cavities, which further reduces the amount of duplication of components required when working with multiple optical cavities.

The wavelength of the incident light beam 112 (also known as the locking wavelength) output from the optical light source 102 is chosen to be a fixed fraction of the transition wavelength of the matter qubit 108. This is called a fixed fraction locking light method.

Using the fixed fraction locking light method to determine a wavelength of the incident light beam 112 ensures that there is at least one optical cavity length wherein the optical cavity 106 is on resonance with both the incident light beam 112 and the transition wavelength of the matter qubit 108. That is, this choice of locking wavelength ensures that a dual-resonance condition, whereby the optical cavity 106 is on resonance with both the incident light beam 112 and the transition wavelength of the matter qubit, can be met.

Furthermore, the locking wavelength may be chosen to be λ₁=λ_{q}*α/b, where α<N, λ_{q} is the fixed transition wavelength of the matter qubit 108, λ₁ is the wavelength of the incident light beam 112, N=z/λ_{q} where N is a number greater than 1 (and not necessarily an integer number), z is a travel range of the actuator 110, and α and b are integers where α/b is a simplified fraction. The fraction α/b is the fixed fraction referred to in the term ‘fixed fraction locking light’, since the locking wavelength is this fixed fraction of the transition wavelength of the matter qubit 108.

This choice of locking wavelength ensures that the dual-resonance condition can be met within a travel range z of the actuator 110. If the wavelength of the incident light beam does not meet this requirement, and instead an arbitrary wavelength is chosen, then there is only guaranteed to be a single optical cavity length at which the dual-resonance condition is met, and that is only if an offset lock or similar is used to slightly tune the arbitrary wavelength (tuning by up to one Free Spectral Range). Without the offset lock, there may not be any optical cavity lengths at which the dual-resonance condition is met. To stabilise the lengths of a plurality of optical cavities using the same optical light source 102 would then require all of the optical cavities to initially be of the same length at least to within the tuning range of the actuator. Selecting an incident light beam 112 wavelength which meets this condition and is a fixed fraction of the transition wavelength of the matter qubit 108 therefore ensures that there is at least one point within the travel range of the actuators 110 such that the dual-resonance condition is met for all of the optical cavities 106.

Ideally, the fraction a b should be as simple as possible since the more complex the fraction a b is, the larger the travel range of the actuator, z, needs to be to ensure that the dual-resonance condition is met. For example, the travel range of the actuator needs to be larger if the wavelength of the incident light beam 112 is chosen to be 17/29 of the transition wavelength of the matter qubit 108, compared to when the travel range of the incident light beam 112 is chosen to be ⅓ of the transition wavelength of the matter qubit 108, in order to guarantee that the dual-resonance condition is met within a travel range of the actuator 110 since 17/29 is a more complex fraction than ⅓. As such, α and b may comprise two integers less than 10, or two numbers less than 5. The fraction α/b may be ½, ⅔, ¾, ⅘, 2/1, 3/2, 4/3 or 5/4. As can be seen, the wavelength of the incident light beam 112 (or locking light) may be larger than or smaller than the transition wavelength of the matter qubit.

Choosing a fixed fraction locking wavelength of the incident light beam 112 in this way allows the required optical cavity length fabrication tolerance for each of the optical cavities to be wider than the corresponding actuator travel range whilst still providing the plurality of lockable optical cavities. This is useful for optical cavity 106 geometries where the absolute value of the cavity length is non-critical, such as in near-confocal geometries.

In practice, it can be difficult to reliably stabilise or lock the length of an optical cavity when the cavity is at either extreme of the actuator travel range due to, for example, thermal expansion of a holder of the optical cavity 106. It may therefore be desirable to further constrain a value α/N so that the dual resonance point of the optical cavity is not provided at or near either of the extremes of the actuator travel range. The exact constraints on a N required to prevent the dual-resonance point of the optical cavity from being so close to an extreme end of the travel range of the actuator that the stability of the cavity locking may be compromised will vary depending on factors such as the precise materials and equipment chosen in the apparatus set-up. For example, a/N will not need to be as constrained in the case where the material of the optical cavity holder is less resistant to thermal expansion compared to the case where the material of the optical cavity holder is more susceptible to thermal expansion.

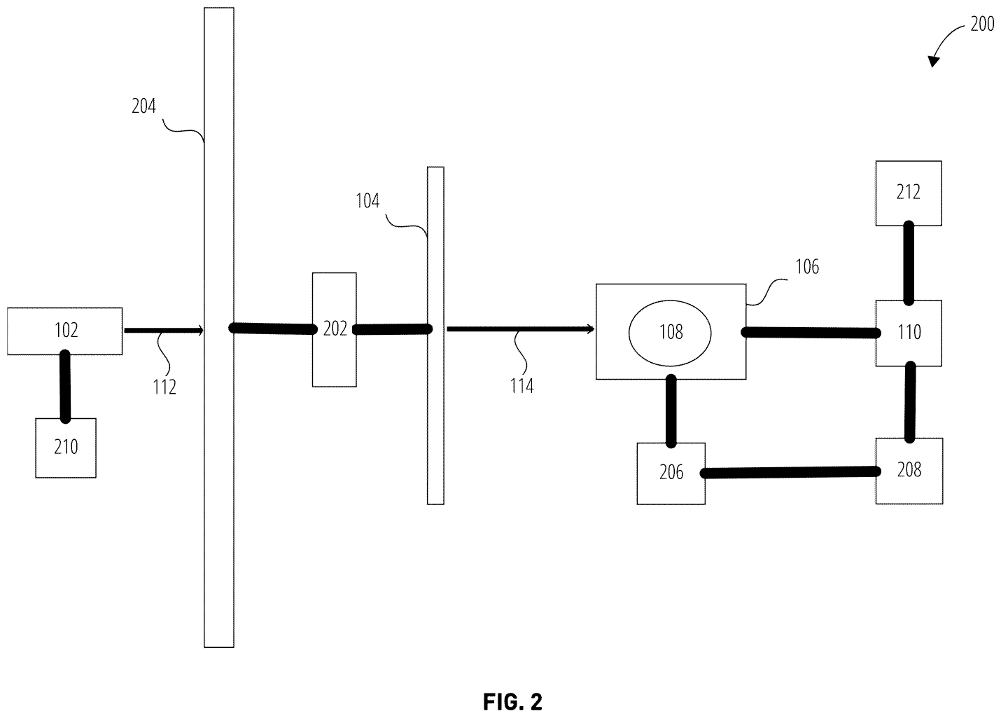

FIG. 2 shows another schematic illustration of an apparatus 200 for locking a plurality of optical cavities in accordance with aspects of the present disclosure. For simplicity, the separating means 104 is being shown to output only a single light beam 114 to a single optical cavity 106. However, it should be understood that, as shown in FIG. 1, the separating means 104 can divide a light beam reaching the separating means into a plurality of light beams 114 which can be used to lock a plurality of optical cavities 106.

In addition to the components shown and described with respect to the apparatus 100 of FIG. 1, the apparatus 200 may further comprise an electro-optic modulator 202 (EOM) arranged between the optical light source 102 and the separating means 104. The EOM may comprise a lithium niobate or MgO: LN-type crystal. An EOM is a device which can modulate a beam of light, which may comprise modulating properties including the intensity, phase, amplitude or polarization of the incident light beam 112.

The EOM 202 is configured to apply a phase shift to modulate the phase or frequency of the incident light beam 112 to allow the optical cavities 106 to be locked using, for example, the Pound-Drever-Hall (PDH) method. This disclosure is not limited to the PDH method, and any appropriate cavity locking techniques, such as side-of-peak and dithering set-ups, may also be used to lock the length of the optical cavities 106.

The PDH method uses phase modulated light from the optical light source 102, received in the optical cavity 106. The phase of the portion of light from the optical light source 102 that is transmitted or reflected from the optical cavity 106 is detected, for example by homodyne detection, to determine the error and the resonant wavelength of the optical cavity 106, compared to the wavelength of the stable optical light source 102, and the detected error is used to feedback to the actuator 110 to correct the length of the optical cavity 106 to be on resonance with the optical light source 102 again. Thus, the PDH technique enables the locking of an optical cavity 106 to an optical light source 102 and enables the measurement of small changes in the length of the optical cavity 106 with extremely high precision. Any small changes in the length of the optical cavity 106 cause the optical cavity 106 to drift out of resonance with the stable wavelength of the light from the optical light source 102 and so cause a change, for example an increase, in the phase error signal detected from the light output from the optical cavity 106 by homodyne detection. By detecting the phase error of the light output from the optical cavity 106, the small change in the length of the optical cavity 106 can be detected and, based on this, the actuator 110 can then adjust the length of the optical cavity 106 to compensate for the small change so that the optical cavity 106 is on resonance with the optical light source 102, known as locking the optical cavity 106 to the optical light source 102.

A limiting factor for the number of optical cavities which can be locked in this manner is an amount of light required by each of the optical cavities. The more light beams 114 that the incident light beam 112 is divided into, the lower the intensity of light of each of the light beams 114. If too little light reaches an optical cavity then a signal to noise ratio of the signal which measures how far the cavity length is from resonance is degraded. This reduces the reliability and robustness of the locking of the length of the optical cavity.

Another limiting factor is the maximum transmission power of the EOM 202, which limits the amount of light which can be output from the single EOM 202. As described above, if too little light reaches the optical cavity 106 then the stability of the locking of the optical cavity 106 is reduced.

There is no exact number for the maximum number of optical cavities which can be locked in this way since it depends on the particular optical cavities 106, EOM 202 and optical light source 102 chosen for the set-up.

If a number of optical cavities 106 to be locked is greater than the number which can be reliably locked using a single EOM at its maximum transmission power, then multiple EOMs can be used. Since optical light sources such as lasers are typically less restricted in the amount of power which can be output than EOMs, the incident light beam 112 from the optical light source 102 can be divided using a second separating means 204 and transmitted to a plurality of EOMs 202. For simplicity, FIG. 2 only shows one light beam being output by the second separating means 204 to a single EOM 202. However, it should be understood that two or more light beams can be output by the second separating means 204 with each of the output light beams being directed to a separate EOM 202 and its corresponding set-up comprising multiple optical cavities 106.

For example, in an apparatus 200 where each EOM 202 enables four optical cavities 106 to be locked and the second separating means 204 enables the incident light beam 112 from the optical light source 102 to be transmitted to three EOMs, then a total of twelve optical cavities may be locked using the single optical light source 102. This is merely exemplary and the disclosure is not intended to be limited to these numbers.

Furthermore, depending on the particular EOMs 202 chosen, each EOM 202 may enable a different number of optical cavities 106 to be locked. That is, one EOM 202 may be capable of locking a maximum of five optical cavities 106 while another EOM 202 may be capable of locking a maximum of four optical cavities 106, and yet another EOM 202 may be capable of locking a maximum of six optical cavities 106. This is also merely exemplary and the disclosure is not intended to be limited to these numbers.

The apparatus 200 may further comprise a measuring means 206 for measuring the amount or fraction of light transmitted or reflected from the corresponding optical cavity 106. The measuring means 206 may comprise a photodetector, such as a coherent detector, which is configured to detect the light transmitted or reflected from the optical cavity 106. The measuring means 206 may provide a feedback signal to a controller 208, where the feedback signal corresponds to the light transmitted or reflected by the optical cavity 106. The feedback signal may be based on the phase of the light output from the optical cavity 106. The measuring means 206 may generate the feedback signal by mixing the detected light signal with a modulation signal from an RF driver and using homodyne detection to reveal a phase difference, which is indicative of a phase error and is used as the feedback signal.

The controller 208 may use the received feedback signal to determine a required amount and direction of adjustment of the optical cavity 106 and output an error signal to the actuator 110 to control the actuator 110 to make adjustments to the length of the optical cavity 106 to lock the optical cavity 106 to the optical light source 102. The controller 208 may be a feedback controller such as a PID controller.

The apparatus 200 may further comprise a stabilising means 210 for stabilising the wavelength of the incident light beam 112 output by the optical light source 102. The stabilising means 210 may generate light at a particular wavelength using a stable reference at the matter qubit transition wavelength. A second harmonic generator may be used to generate the light for locking the optical light source.

Furthermore, when the wavelength of the incident light beam 112 is chosen according to the fixed fraction locking wavelength method, and if light at the transition wavelength of the matter qubit 108 can easily be generated, then a second harmonic generator or similar (such as a third harmonic generator), can be used to directly generate the locking light (or incident light beam 112) without the need for any form of optical light source offset lock. For example, if the matter qubit 108 in the optical cavity comprises an alkali element, then a vapour cell can provide the exact matter qubit transition wavelength as a reference. The frequency of the matter qubit transition wavelength can then be, for example, doubled to generate the required frequency of the locking light.

The apparatus 200 may also comprise a scanning means 212, such as a scanner, for scanning the actuator. The scanner may be used to locate the resonant point where both the optical cavity and the matter qubit are on resonance.

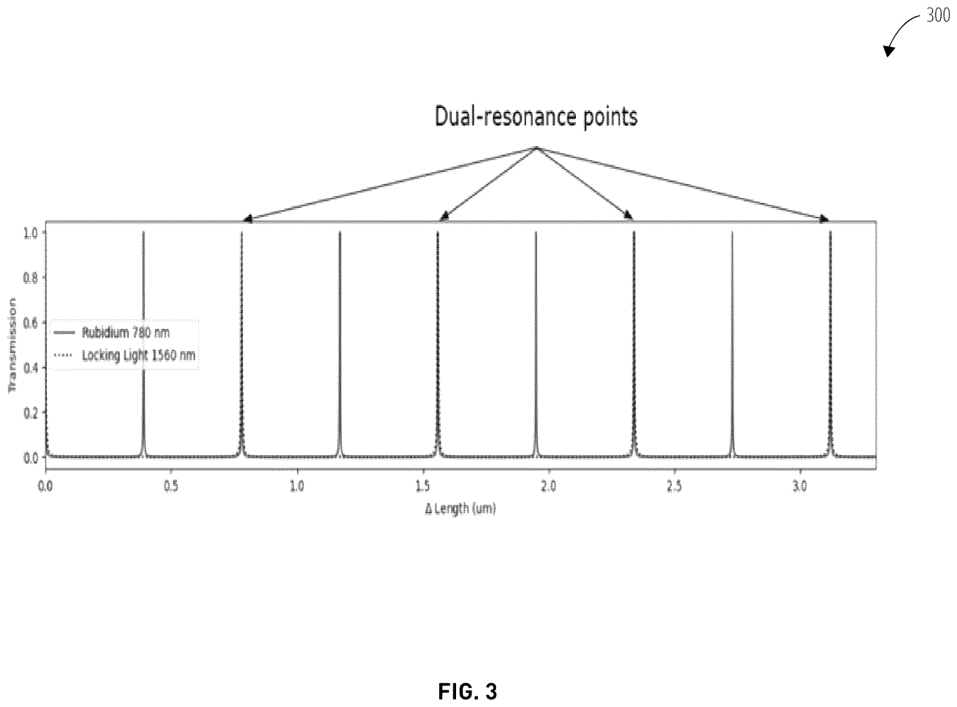

FIG. 3 shows the transmission of light through an optical cavity 106 at both the incident light beam 112 (locking) wavelength λ₁ and a single photon emitter wavelength λₑ at a ratio λₑ: λ₁ of 1:2. Although, in this case, a single photon emitter is provided in the optical cavity 106 in place of a matter qubit 108, the skilled person would understand that these components are interchangeable and the same principles apply regardless of whether the material in the optical cavity is being used as a single photon emitter material or a matter qubit 108. Indeed, in many cases the single photon emitter and the matter qubit are the same material. The methods and principles described in relation to the single photon emitter (for example, a solid state emitter such as nano-diamond, quantum dots or hexagonal boron nitride) in this Figure therefore apply equally to the matter qubit 108 of the present disclosure.

In this particular example, the material within the optical cavity 106 comprises a neutral atom rubidium (Rb) 87 with D2 line transitions occurring at 780 nm. A 1:2 emitter to locking light wavelength ratio is chosen so that a standard 1560 nm telecoms laser can be used as the optical light source 102 to stabilise the length of the optical cavity 106.

FIG. 3 shows the resonance points for both the 780 nm Rb light and the incident light beam 112 output from the laser, where the incident light beam 112 has a wavelength double that of the Rb cell. Since the locking light wavelength is exactly double that of the Rb emitter, every locking light resonance has a corresponding emitter resonance. Since resonances occur every integer number of half wavelengths, there is therefore a viable dual-resonance lock point every 780 nm. That is, the dual-resonance condition where the optical cavity 106 is simultaneously on resonance with both the light from the optical light source 102 and the emitted light from the Rb cell is met every 780 nm. These points are shown in FIG. 3. This lock point is well within a standard piezo actuator 110 travel range of a few microns, so all of the optical cavities 106 can be stabilised using the same reference and optical light source 102.

To ensure that the wavelength of the incident light beam 112 emitted by the laser is exactly double that of the chosen Rb transition wavelength, the laser can be stabilised by reference to a separate Rb cell.

A second harmonic generator (SHG) can be used to generate light at 780 nm, the D2 transition wavelength of Rb. A portion of the light output from the laser is separated using another separating means, such as an optical splitter, and passed through the SHG. Light is then emitted from the SHG at 780 nm and absorbed by a vapour within the Rb cell when on or near the atomic resonance of the cell. This can then be used as a reference to stabilise the laser, using a saturated absorption spectroscopy lock.

There are many ways in which the modulation required to lock the laser can be provided. For example, a piezo actuator provided inside the laser can be dithered. Alternatively, atoms can be modulated directly by wrapping a coil around the Rb cell and modulating this. Alternatively, an EOM can be provided before the separating means which separates the portion of light from the laser to the SHG, to allow the same EOM to lock both the laser and the lengths of the optical cavities.

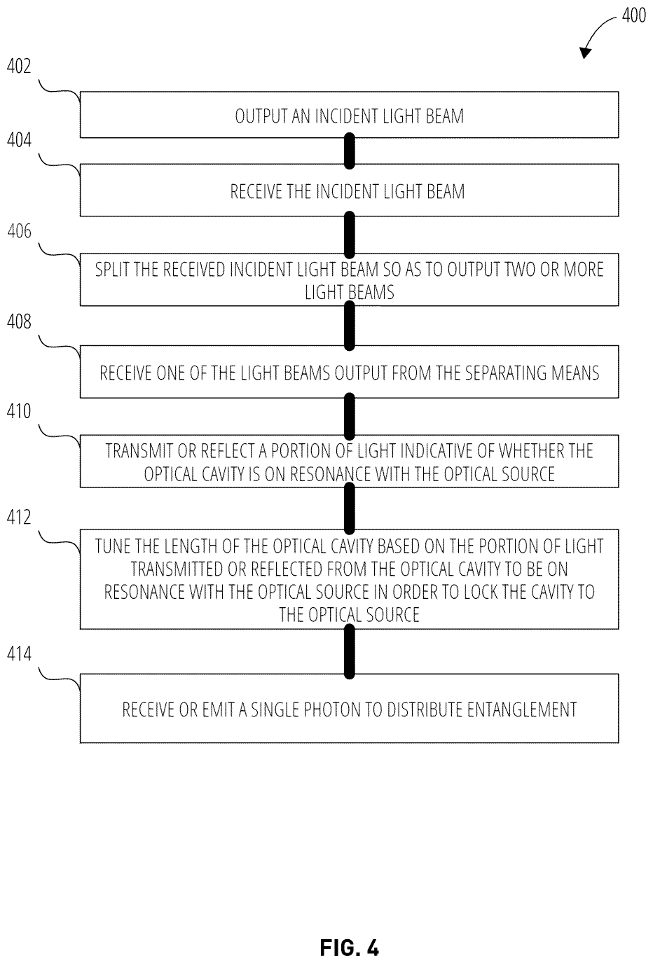

FIG. 4 shows a method 400 for locking the lengths of a plurality of optical cavities 106 in accordance with an embodiment of the invention. The method 400 may be performed by the apparatus 100 of FIG. 1 or the apparatus 200 of FIG. 2. The method may be performed during use of the apparatus.

The method comprises outputting 402, by an optical light source 102, an incident light beam 112. The method further comprises receiving 404, at a separating means 104, the incident light beam output from the optical light source 102. The method additionally comprises splitting 408, by the separating means 104, the received incident light beam so as to output two or more light beams 114. The method further comprises receiving 408, at each of a plurality of optical cavities 106 one of the light beams 114 transmitted or output from the separating means 104. Each of the plurality of optical cavities contains a matter qubit 108 configured to capture photons to distribute quantum entanglement, wherein a rate of entanglement is enhanced by the Purcell effect. The type of matter qubit 108 is the same for each of the optical cavities 106.

The method additionally comprises transmitting or reflecting 410, by each optical cavity 106 of the plurality of optical cavities 106, a portion of light indicative of whether the optical cavity is on resonance with the optical light source 102. The method may also comprise measuring, by a measuring means 206, the portion of light transmitted or reflected from the optical cavity.

The method further comprises tuning 412, by each of a plurality of actuators 110 connected to a corresponding optical cavity 106, the length of the corresponding optical cavity 106 based on the portion of light transmitted or reflected from said optical cavity 106 such that the optical cavity is on resonance with the optical optical light source 102 in order to lock the optical cavity 106 to the optical light source 102. This may be achieved using a measuring means 206 to provide a feedback signal to a controller 208, where the feedback signal corresponds to the light transmitted or reflected by the optical cavity 106. The tuning of the length of an optical cavity 106 may further comprise the controller 208 using the received feedback signal to determine a required amount and direction of adjustment of the optical cavity 106. The tuning of the length of the optical cavity may also involve the controller 208 outputting an error signal to the actuator 110 to control the actuator 110 to make adjustments to the length of the optical cavity 106 to lock the optical cavity 106 to the optical light source 102. A single photon may then be received by or emitted from the matter qubit to distribute quantum entanglement 414.

The incident light beam 112 which is output from the optical light source 102 is detuned by a ratio of two integers, α and b, where α/b denotes a fixed fraction, from a transition wavelength of the matter qubit 108 to ensure that, for each optical cavity 106, there is at least one point within a travel range of the actuator 110 where a dual-resonance condition is met. When the dual-resonance condition is met, the optical cavity is simultaneously resonant with both the matter qubit 108 and the incident light beam 112.

In particular, the wavelength of the incident light beam 112 may be chosen to be λ₁=λ_{q}*α/b, where α<N, λ_{q} is the fixed transition wavelength of the matter qubit 108, λ₁ is the wavelength of the incident light beam 112, N=z/λ_{q} where N is a number greater than 1 and not necessarily an integer number, and z is a travel range of the actuator 110.

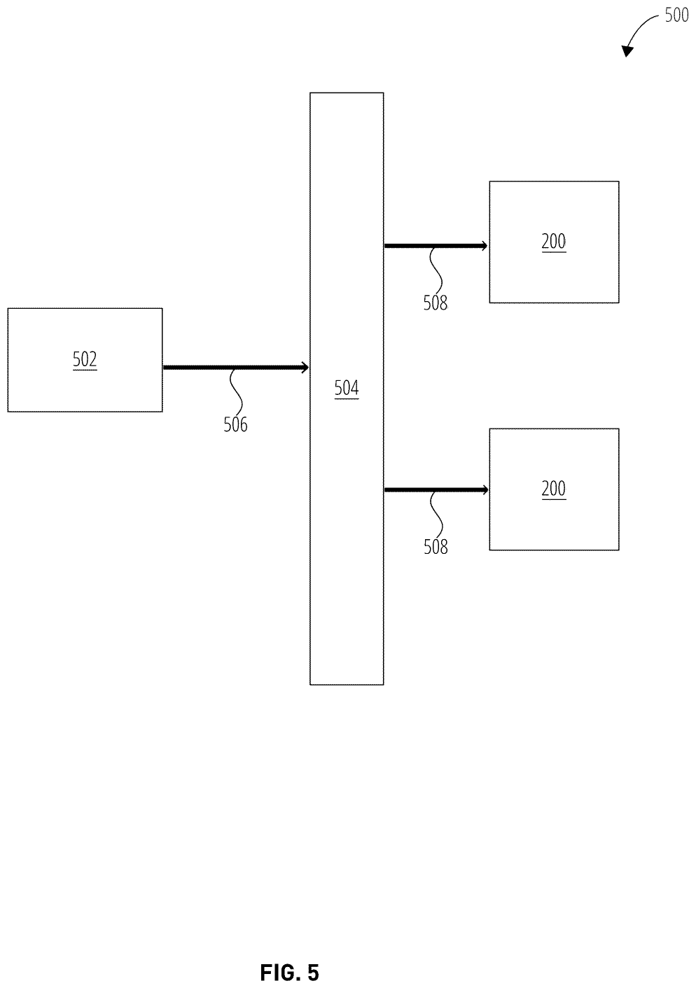

FIG. 5 shows an example system demonstrating how the apparatus can be scaled up to allow an even greater number of optical cavities 106 to be locked at the same time. As mentioned above, one of the limiting factors in the number of optical cavities which can be locked using the same optical light source 102 is the amount of light which can be output by a single EOM 202. One way to overcome this limitation is to provide a second separating means 204 between the optical light source 102 and the EOM 202 to enable the incident light beam 112 output from the optical light source 102 to be sent to a plurality of EOMs, which in turn can each be used to lock a plurality of optical cavities 106. The number of optical cavities 106 which can then be locked is limited by the maximum output power of the optical light source 102.

One way to scale the set up to allow even more optical cavities to be locked is to use multiple optical light sources. Using a single stable reference optical light source 502, such as a laser, multiple smaller and cheaper optical light sources 102 can be offset-locked relative to the reference optical light source 502.

A reference incident light beam 506 at a desired wavelength is output by the reference optical light source 502 and received at a reference separating means 504. The reference separating means 504 splits or divides the reference incident light beam 506 into a plurality of reference light beams 508. The reference light beams 508 can then be used to lock the optical light sources 102 of each of a plurality of apparatus 200 set-ups.

FIG. 5 shows the reference incident light beam 506 being divided into two reference light beams 508, which are in turn sent to two apparatus 200 set-ups. However, this is merely exemplary and two apparatus 200 set-ups have been chosen in this case to keep FIG. 5 clear. It is to be understood that the reference incident light beam 506 may be divided into any number of reference light beams 508, each of which may be transmitted to an apparatus 200 set-up to lock the optical light source 102 of said apparatus 200 set-up.

For example, if each apparatus 200 enables twelve optical cavities to be locked using the single optical light source 102, and the reference separating means 504 allows light from the reference optical light source 502 to be used to lock five of the optical light sources 102, then a total of 60 optical cavities 108 can be locked using the single reference optical light source 502. This is merely exemplary and the disclosure is not intended to be limited to these numbers.

If a maximum transmission power of the reference optical light source 502 is reached and it is still necessary to lock more optical cavities, then the system can be scaled up further by daisy chain locking more reference optical light sources 502 together. For example, a light beam may be output from an even more powerful optical light source and divided, using an additional separating means, into a plurality of light beams which are in turn used to stabilise a plurality of reference optical light sources 502. This is only an example, and the skilled person would recognise that there are many ways in which the apparatus could be scaled further. Alternative approaches could include, for example, using optical-transfer cavity locking, multi-pass atomic reference cells, or alternative designs for optimally utilising single stable references.

The apparatus described with reference to FIGS. 1 to 5 works best in ideal, or near ideal conditions. It assumes that the wavelength of the locking light from the optical light source 102 and the wavelength of the qubit 108 both reflect off the mirrors of the optical cavity in the same manner. In practice, this can be difficult to achieve for many reasons. For example, the optical coatings on the mirrors have an inherent penetration depth, so the wavelength of the locking light and the wavelength of the matter qubit may penetrate different distances into the optical coating. Furthermore, when light reflects off a curved surface, the light may experience a phase shift.

These effects can cause the effective cavity length experienced by the locking light wavelength and the matter qubit wavelength to differ, which may cause imperfections in the fixed fraction resonance position. When this happens, the cavity resonances may no longer occur at precisely a half integer number of wavelengths.

The apparatus described in FIGS. 1 to 5 obtains best results when a custom coating which compensates for the abovementioned effects is used on the mirrors of the optical cavities, and when the optical cavity mirrors are manufactured to within very tight tolerances.

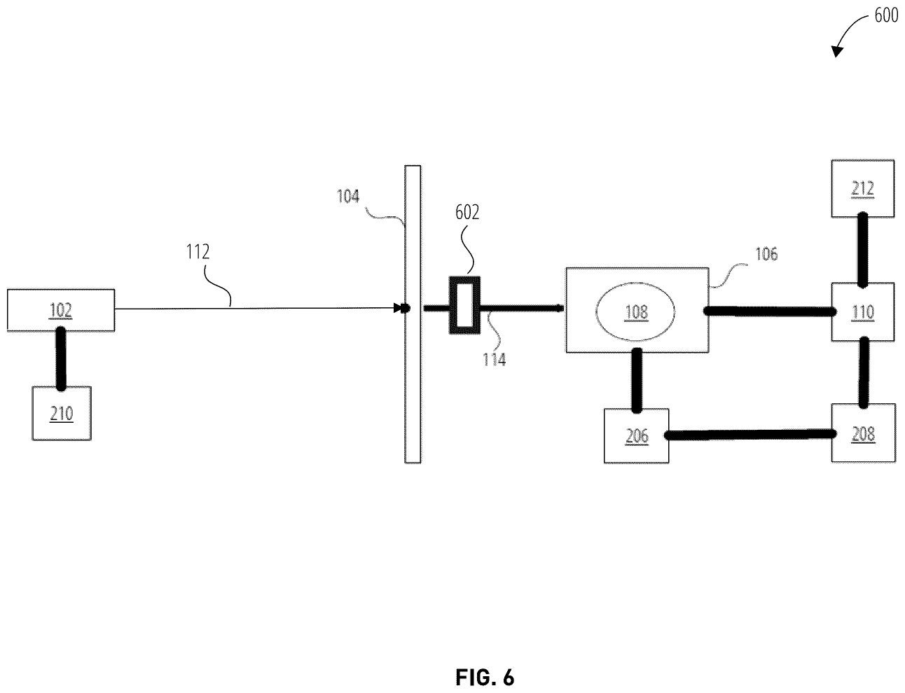

FIG. 6 is a schematic illustration of an apparatus 600 for locking a plurality of optical cavities in accordance with aspects of the present disclosure.

The apparatus 600 comprises an optical light source 102, a separating means 104, a plurality of optical cavities 106, and an actuator 110. For clarity, only one optical cavity 106 is shown in FIG. 6, but the skilled person would readily understand that any number of optical cavities 106 may be provided. Each optical cavity contains a matter qubit 108.

Apparatus 600 further comprises a modulator 602 provided between the separating means 104 and the optical cavity 106. Each optical cavity of the plurality of optical cavities is provided with a modulator 602 between the optical cavity and the separating means.

Each modulator 602 is configured to apply a phase shift to the incident light beam 112 output by the optical light source to modulate the phase and frequency of the incident light beam 112 to allow the optical cavities 106 to be locked using, for example, the Pound-Drever-Hall (PDH) method. The modulator 602 may therefore perform the function described in relation to the EOM 202, so a detailed description thereof is not repeated. Each modulator 602 of the plurality of modulators 602 may modulate the phase and frequency of the incident light beam by the same amount to enable the corresponding optical cavity 106 to be locked.

The modulator 602 is also configured to apply a small additional frequency shift to the modulated incident light beam to fine tune the frequency of the incident light beam. The amount of the small additional frequency shift required for each optical cavity may be different because each optical cavity may have marginally different mirror curvatures with different optical coating properties due to manufacturing tolerances. Each modulator 602 of the plurality of modulators 602 may therefore apply a different small additional frequency shift to the modulated incident light beam so that each optical cavity is individually calibrated for the locking.

The apparatus 600 may further comprise additional components, such as one or more of the components discussed in relation to FIG. 2.

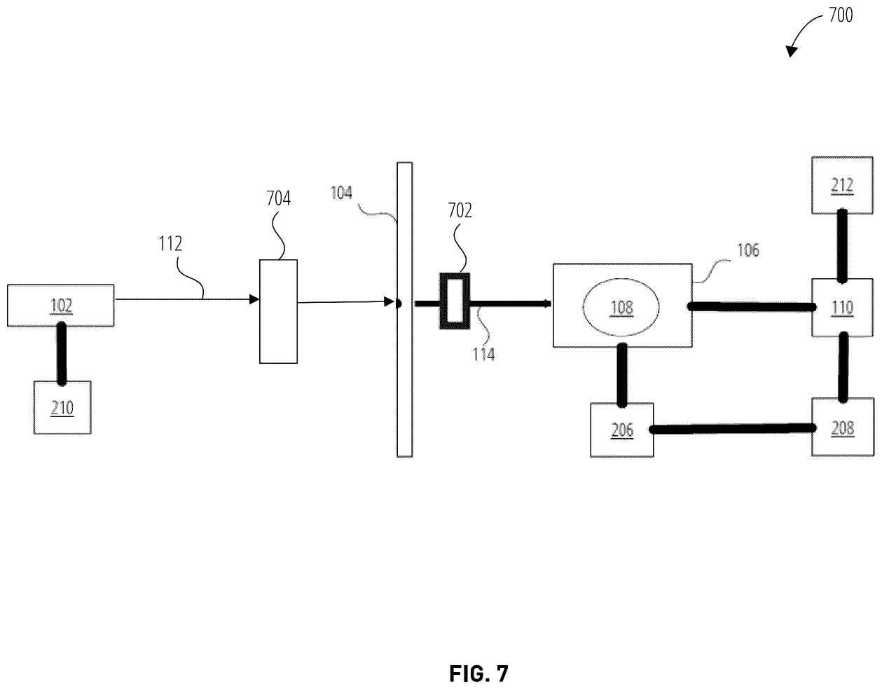

FIG. 7 is a schematic illustration of another apparatus 700 for locking a plurality of optical cavities in accordance with aspects of the present disclosure.

The apparatus 700 comprises a first modulator 702 and a second modulator 704. Each optical cavity of the plurality of optical cavities is provided with a first modulator 702 between the optical cavity and the separating means 104. The second modulator 704 is provided between the optical light source 102 and the separating means 104.

The second modulator 704 may be an EOM. The second modulator 704 may be the EOM 202. The second modulator 704 modulates the incident light beam 112 for each of the plurality of optical cavities 106, so that the second modulator 704 effectively acts on all of the optical cavities 106 which receive a light beam via the separating means 104.

The first modulator 702 may be an EOM or an acousto-optic modulator. The first modulator 702 further modulates the modulated incident light beam from the second modulator 704. This provides the small additional frequency shift to account for the non-uniformity of the optical cavities. Each of the first modulators 702 may apply a different frequency shift so that each optical cavity is individually optimized for the locking.

The tunability required to compensate for the effects of the tolerances on the optical coatings and other manufacturing tolerances is significantly less than the tunability required to account for other effects shared between cavities, to ensure dual resonance condition is met. As such, the second modulator 704 may perform a larger modulation than the first modulator 702.

For both the apparatus 600 and the apparatus 700, the incident light beam output from optical light source 102 is tuned close to the correct wavelength for the optical cavities. The correct wavelength is close to the fixed fraction wavelength, where the fixed fraction wavelength is subjected to a small amount of detuning to optimise for penetration depth and radius of curvature effects. A small additional frequency shift is then applied per cavity using the fine frequency shift element, in order to account for residual shifts and manufacturing tolerances. The first broad frequency shift could be provided by the second modulator 704 (as shown in apparatus 700) or by direct tuning of the frequency of the reference light (such as with a frequency comb).

The second modulator 704 may be an EOM with a tuning range on the order of 10 GHz. The first modulator 702 may be an EOM or an acousto-optic modulator. A typical acousto-optic modulator has a tuning range on the order of 0.1 GHz.

Since a first modulator 702 is required for each optical cavity whereas a second modulator 704 may be used for a plurality of optical cavities, it may be desirable to use a cheaper modulator as the first modulator 702 to reduce the overall cost of the apparatus 700. AOMs tend to cost less than EOMs, so the first modulator may preferably be an AOM. Where both the first modulator 702 and the second modulator 704 are EOMs, the first modulator may be a lower-quality or cheaper EOM than the second modulator 704. The tunability required to ensure that the dual resonance condition is met is greater than the tunability provided by a typical AOM. Therefore, an AOM is typically not an appropriate choice for the second modulator 704.

1. An apparatus for stabilising the length of a plurality of optical cavities, the apparatus comprising:
an optical light source configured to output an incident light beam;
a separating means configured to receive the incident light beam output from the optical source and split the received incident light beam so as to output two or more light beams; and
a plurality of optical cavities, wherein each optical cavity of the plurality of optical cavities is configured to:
receive one of the light beams output from the separating means;
transmit or reflect a portion of light indicative of whether the optical cavity is on resonance with the optical light source;
be connected to an actuator, the actuator configured to tune the length of the optical cavity based on the portion of light transmitted or reflected from the optical cavity to be on resonance with the optical source in order to lock the optical cavity to the optical source; and
contain a matter qubit within the optical cavity, the matter qubit configured to capture photons to distribute quantum entanglement, wherein a rate of entanglement is enhanced by the Purcell effect;
wherein the matter qubit is the same for each optical cavity; and
wherein the incident light beam is detuned by a ratio of two integers, a and b where a b denotes a fixed fraction, from a transition wavelength of the matter qubit to ensure that, for each optical cavity, there is at least one point within a travel range of the actuator where a dual-resonance condition is met such that the optical cavity is simultaneously resonant with the matter qubit and the incident light beam.

2. The apparatus of claim 1, further comprising, for each optical cavity of the plurality of optical cavities, a first modulator arranged between the separating means and the optical cavity.

3. The apparatus of claim 2, wherein the first modulator is an electro-optic modulator, EOM, or an acousto-optic modulator, AOM.

4. The apparatus of any one of claims 1 to 3, further comprising a second modulator arranged between the optical light source and the separating means to apply a phase shift to the incident light beam, wherein the second modulator is an electro-optic modulator.

5. The apparatus of claim 4, further comprising a second separating means arranged between the optical light source and the second modulator to split the incident light beam into a plurality of incident light beams.

6. The apparatus of any one of claims 1 to 5, further comprising, for each optical cavity, a measuring means for measuring a fraction of light transmitted or reflected from the optical cavity.

7. The apparatus of any one of claims 1 to 6, further comprising, for each actuator, a scanning means for scanning the actuator.

8. The apparatus of any one of claims 1 to 7, wherein the wavelength of the incident light beam is chosen to be λ₁=λ_{q}*a/b, where a<N,
where λ_{q} is the transition wavelength of the matter qubit and is fixed, λ₁ is the wavelength of the incident light beam, N=z/λ_{q} where N is a number greater than 1 and not necessarily an integer number, z is a travel range of the actuator, α and b are the integers of claim 1, where a/b is a simplified fraction.

9. The apparatus of any one of claims 1 to 8, wherein a and b are 10 or less, optionally wherein a and b are 5 or less.

10. The apparatus of claim 9, wherein the ratio of the wavelength of the incident light beam to the wavelength of the matter qubit is 1:2, 2:3, 3:4, 4:5, 2:1, 3:2, 4:3 or 5:4.

11. The apparatus of any one of claims 1 to 10, wherein the wavelength of the incident light beam is within a range 600-1600 nm.

12. The apparatus of any one of claims 1 to 11, wherein the separating means is an optical splitter.

13. The apparatus of any one of claims 1 to 12, wherein the matter qubit comprises a neutral atom or a trapped ion.

1. An apparatus for stabilising the length of a plurality of optical cavities, the apparatus comprising:
an optical light source configured to output an incident light beam:
a separating means configured to receive the incident light beam output from the optical source and split the received incident light beam so as to output two or more light beams; and
a plurality of optical cavities, wherein each optical cavity of the plurality of optical cavities is configured to:
receive one of the light beams output from the separating means:
transmit or reflect a portion of light indicative of whether the optical cavity is on resonance with the optical light source:
be connected to an actuator, the actuator configured to tune the length of the optical cavity based on the portion of light transmitted or reflected from the optical cavity to be on resonance with the optical source in order to lock the optical cavity to the optical source; and
contain a matter qubit within the optical cavity, the matter qubit configured to capture photons to distribute quantum entanglement, wherein a rate of entanglement is enhanced by the Purcell effect:
wherein the matter qubit is the same for each optical cavity; and
wherein the incident light beam is detuned by a ratio of two integers, a and b where a/b denotes a fixed fraction, from a transition wavelength of the matter qubit to ensure that, for each optical cavity, there is at least one point within a travel range of the actuator where a dual-resonance condition is met such that the optical cavity is simultaneously resonant with the matter qubit and the incident light beam.

2. The apparatus of claim 1, further comprising, for each optical cavity of the plurality of optical cavities, a first modulator arranged between the separating means and the optical cavity.

3. The apparatus of claim 2, wherein the first modulator is an electro-optic modulator, EOM, or an acousto-optic modulator, AOM.

4. The apparatus of claim 1, further comprising a second modulator arranged between the optical light source and the separating means to apply a phase shift to the incident light beam, wherein the second modulator is an electro-optic modulator.

5. The apparatus of claim 4, further comprising a second separating means arranged between the optical light source and the second modulator to split the incident light beam into a plurality of incident light beams.

6. The apparatus of claim 1, further comprising, for each optical cavity, a measuring means for measuring a fraction of light transmitted or reflected from the optical cavity.

7. The apparatus of claim 1, further comprising, for each actuator, a scanning means for scanning the actuator.

8. The apparatus of claim 1, wherein the wavelength of the incident light beam is chosen to be λ1=λq*a/b, where a<N,
where λq is the transition wavelength of the matter qubit and is fixed, λ1 is the wavelength of the incident light beam, N=z/λq where N is a number greater than 1 and not necessarily an integer number, z is a travel range of the actuator, a and b are the integers of claim 1, where a/b is a simplified fraction.

9. The apparatus of claim 1, wherein a and b are 10 or less, optionally wherein a and b are 5 or less.

10. The apparatus of claim 9, wherein the ratio of the wavelength of the incident light beam to the wavelength of the matter qubit is 1:2, 2:3, 3:4, 4:5, 2:1, 3:2, 4:3 or 5:4.

11. The apparatus of claim 1, wherein the wavelength of the incident light beam is within a range 600-1600 nm.

12. The apparatus of claim 1, wherein the separating means is an optical splitter.

13. The apparatus of claim 1, wherein the matter qubit comprises a neutral atom or a trapped ion.

14. The apparatus of claim 1, wherein the actuator is a piezo actuator.

15. The apparatus of claim 1, wherein the optical light source is a laser.

16. The apparatus of claim 1, wherein each of the optical cavities includes a dual-band coating.

17. The apparatus of claim 1, further comprising, for each of the optical cavities, a locking means to stabilise a length of the optical cavity.

18. The apparatus of claim 1, wherein the actuator is configured to lock each of the optical cavities to be on resonance with the optical light source using a Pound-Drever-Hall technique, a side-of-peak locking technique, or a dither locking technique.

19. The apparatus of claim 1, for use in quantum computing and/or quantum networking applications.

20. The apparatus of claim 1, further comprising a stabilising means for stabilising the optical light source.

21. The apparatus of claim 20, wherein the stabilising means generates fixed fraction locking light at a fixed fraction wavelength using a stable reference at a qubit transition wavelength.

22. The apparatus of claim 21, further comprising a second harmonic generator or an optical transfer cavity for generating the fixed fraction locking light.

23. The apparatus of claim 20, wherein the optical light source is stabilised by reference to an atomic vapour cell or an optical frequency comb.

24. The apparatus of claim 23, wherein the optical light source is stabilized by reference to a HeNe laser, or the atomic vapour cell comprises a Rb cell.

25. A system for stabilising the length of a plurality of optical cavities, the system comprising:
at least two apparatuses according to claim 1;
a reference optical source configured to output a reference incident light beam; and
a reference separating means configured to receive the reference incident light beam output from the reference optical source and split the received reference incident light beam so as to output two or more reference light beams;
wherein each optical light source of the at least two apparatuses is stabilised by reference to one of the output reference light beams.

26. A method for stabilising the length of a plurality of optical cavities, the method comprising:
outputting, by an optical light source, an incident light beam;
receiving, at a separating means, the incident light beam output from the optical source:
splitting, by the separating means, the received incident light beam so as to output two or more light beams:
and, for each optical cavity of a plurality of optical cavities:
receiving one of the light beams output from the separating means:
transmitting or reflecting a portion of light indicative of whether the optical cavity is on resonance with the optical light source:
tuning, by an actuator connected to the optical cavity, the length of the optical cavity based on the portion of light transmitted or reflected from the optical cavity to be on resonance with the optical source in order to lock the optical cavity to the optical source; and
capturing, by a matter qubit located in the optical cavity, photons to distribute quantum entanglement, wherein a rate of entanglement is enhanced by the Purcell effect;
wherein the matter qubit is the same for each optical cavity; and
wherein the incident light beam is detuned by a ratio of two integers, a and b where a/b denotes a fixed fraction, from a transition wavelength of the matter qubit to ensure that, for each optical cavity, there is at least one point within a travel range of the actuator where a dual-resonance condition is met such that the optical cavity is simultaneously resonant with the matter qubit and the incident light beam.

27. The method of claim 26 further comprising, for each optical cavity:
measuring, by a measuring means, the portion of light to determine a fraction of light transmitted or reflected from the optical cavity.

28. The method of claim 27 further comprising:
locking, by a locking means, a length of the optical cavity when the determined fraction of light transmitted or reflected is within a predetermined range.

29. The method of claim 28, wherein the length of the optical cavity is locked when the determined fraction of light transmitted is at a maximum or when the determined fraction of light reflected is at a minimum.

30. The method of claim 28, wherein the optical cavity is locked using a Pound-Drever-Hall technique, a side-of-peak locking technique, or a dither locking technique.
